(19) United States
(12) Patent Application Publication
(10) Pub. No.: US 2012/0102813 A1
(43) Pub. Date: May 3, 2012

(54) JIG-RITE

(76) Inventor: George Rosemann, Fenton, MO (US)

(21) Appl. No.: 12/917,518

(22) Filed: Nov. 2, 2010

(51) Int. Cl. A01K 97/01; H05K 13/00; B23P 11/00; A01K 97/00

(52) U.S. Cl. 43/19.2; 43/26.1; 29/592.1; 29/428

(57) ABSTRACT

One example embodiment includes a system for automatically jigging a lure. The system includes a fishing pole. The fishing pole includes a tip and fishing line, where the fishing line passes through the tip. The system also includes a motor, where the motor is configured to move the tip of the fishing pole.

### CROSS-REFERENCE TO RELATED APPLICATIONS

Not applicable.

### BACKGROUND OF THE INVENTION

Angling, or fishing, is an activity participated in by people around the world. Some individuals fish for sport while others fish for sustenance. The angler attempts to present a lure or bait to a fish. The lure or bait includes a hook, such that when the fish swallows the lure or bait, the fish also swallows the hook, which catches in the soft tissue of the fish's mouth and allows the angler to bring the fish to the surface or to the shore where the angler can retrieve the fish.

A popular method of angling is jigging. In jigging, the angler attempts to move a lure in a pattern that mimics prey of the target fish. Nevertheless, there are a number of difficulties in jigging. In particular, moving the lure too far, or not far enough, can make the motion of the lure unrealistic thus scaring the target fish or failing to catch the interest of the target fish.

Additionally, the angler must get the depth of the lure and the timing of the jig correct in order to convince the fish to take the lure. While experienced anglers can get the correct timing and motion, inexperienced anglers may have difficulty in getting everything correct.

Further, in some instances the angler does not want to do the jigging themselves. In particular, in ice fishing the angler is often outside in the cold or other uncomfortable conditions, such as wind or snow. Because of the conditions the angler may prefer not to do the jigging because to do so they may have to remove gloves or other protective clothing. While the angler may be willing to do so for some activities, he or she may prefer to do so for only short periods of time for specific activities.

Accordingly, there is a need in the art for a system that can be used to produce a jig with the correct timing. In addition, there is a need in the art for a system that can be used to produce a jig of the correct speed. Further there is a need in the art for a system that can be used to produce a jig of the correct displacement.

### BRIEF SUMMARY OF SOME EXAMPLE EMBODIMENTS

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

One example embodiment includes a system for automatically jigging a lure. The system includes a fishing pole. The fishing pole includes a tip and fishing line, where the fishing line passes through the tip. The system also includes a motor, where the motor is configured to move the tip of the fishing pole.

Another example embodiment includes a system for automatically jigging a lure. The system includes a housing, where the housing is configured to enclose at least a portion of the system, and a fishing pole. The fishing pole includes a reel and a tip. The fishing pole also includes fishing line, where the fishing line is wound around the reel and passes through the tip, and a lure. The lure is attached to the fishing line and includes a hook. The lure is also configured to attract and catch fish. The system also includes a solenoid, where the solenoid is configured to move the fishing pole from a first position relative to the housing to a second position relative to the housing, and a power source, where the power source is configured to provide power to the solenoid. The system further includes a switch, where the switch is configured to activate the solenoid and a spring, where the spring is configured to return the fishing pole from the second position to the first position.

Another example embodiment includes a method of manufacturing a system for automatically jigging a lure. The method includes providing a fishing pole.

The fishing pole includes a tip and fishing line, where the fishing line passes through the tip. The method also includes providing a motor, where the motor is configured to move the tip of the fishing pole.

These and other objects and features of the present invention will become more fully apparent from the following description and appended claims, or may be learned by the practice of the invention as set forth hereinafter.

### BRIEF DESCRIPTION OF THE DRAWINGS

To further clarify various aspects of some example embodiments of the present invention, a more particular description of the invention will be rendered by reference to specific embodiments thereof which are illustrated in the appended drawings. It is appreciated that these drawings depict only illustrated embodiments of the invention and are therefore not to be considered limiting of its scope. The invention will be described and explained with additional specificity and detail through the use of the accompanying drawings in which:

FIG. 1 illustrates an example of a system for automatically jigging a fishing lure;

FIG. 2A illustrates a top view of a housing;

FIG. 2B illustrates a side view of the housing; and

FIG. 3 is a flow chart illustrating a method for manufacturing a system for automatically jigging a lure.

### DETAILED DESCRIPTION OF SOME EXAMPLE EMBODIMENTS

Reference will now be made to the figures wherein like structures will be provided with like reference designations. It is understood that the figures are diagrammatic and schematic representations of some embodiments of the invention, and are not limiting of the present invention, nor are they necessarily drawn to scale.

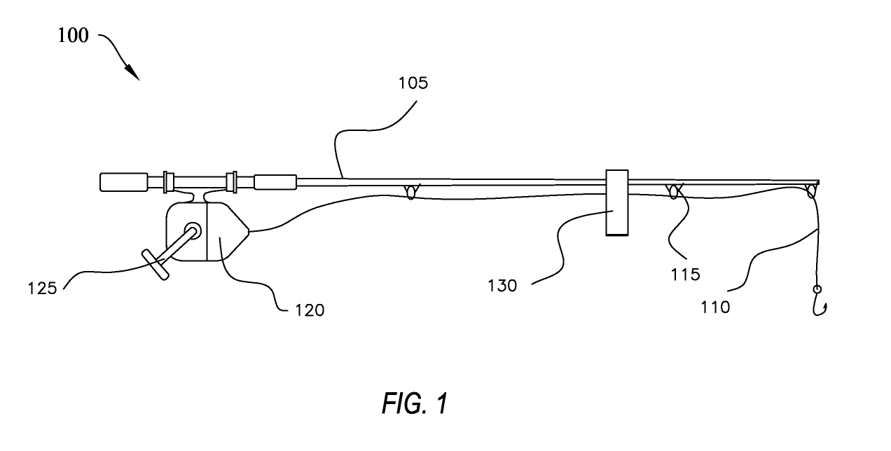

FIG. 1 illustrates an example of a system 100 for automatically jigging a fishing lure. In at least one implementation, jigging a fishing lure includes moving the lure with a jerky or bobbing motion. That is, the lure is jerked up and down or to and fro in order to attract fish to the lure. In particular, the system 100 moves the lure in a manner that attempts to simulate the motion of a fish's prey, thus allowing the angler to catch the fish.

FIG. 1 shows that the system 100 includes a fishing pole 105. In at least one implementation, the fishing pole 105, also called a fishing rod, is a tool used to catch fish. The fishing pole 105 can include a simple pole or stick. The fishing pole 105 can be made of fiberglass, carbon fiber, graphite, bamboo or any other suitable material. The fishing pole 105 can vary in action as well as length, and can be found in sizes between 24 inches and 20 feet. The longer the rod, the greater the mechanical advantage in casting.

The fishing pole 105 can include any type of fishing pole. For example, the fishing pole 105 can include carbon fiber rods, fly rods, spin and bait casting rods, spinning rods, ultra-light rods, ice rods, sea rods, surf rods, trolling rods, telescopic rods or tenkara rods. One of skill in the art will appreciate that the system 100 can be used with any type of fishing pole 105 as described below. There are several specifications manufacturers use to delineate rod uses including power, action, line weight, lure weight, and number of pieces.

Power is often an indicator of what types of fishing, species of fish, or size of fish a particular fishing pole 105 may be best used for. Also known as “power value” or “rod weight.” Fishing poles 105 may be classified as ultra-light, light, medium-light, medium, medium-heavy, heavy, ultra-heavy, or other similar combinations. Ultra-light fishing poles 105 can be used for catching small bait fish and also panfish, or situations where fishing pole 105 responsiveness is critical. Ultra-heavy fishing poles 105 can be used in deep sea fishing, surf fishing, or for heavy fish by weight. While manufacturers use various designations for a fishing pole's 105 power, there is no fixed standard, hence application of a particular power tag by a manufacturer is somewhat subjective. Any fish can theoretically be caught with any fishing pole 105, but catching panfish on a heavy fishing pole 105 offers no sport whatsoever, and successfully landing a large fish on an ultra-light fishing pole 105 requires supreme fishing pole 105 handling skills at best, and more frequently ends in broken tackle and a lost fish. Fishing poles 105 are best suited to the type of fishing they are intended for.

“Action” refers to the responsiveness of the fishing pole 105 to bending force (bending curve), and the speed with which the fishing pole 105 returns to its neutral position. An action may be slow, medium, fast, or a combination (e.g. medium-fast). Fast action fishing poles 105 flex most in the tip section. Slow fishing poles 105 flex more towards the butt of the fishing pole 105. The construction material and construction method of a fishing pole 105 can affect its action. Action, however, is also often a subjective description of a manufacturer; some manufacturers list the power value of the fishing pole 105 as its action. A “medium” action bamboo fishing pole 105 may have a faster action than a “fast” fiberglass fishing pole 105. Action is also subjectively used by anglers, as an angler might compare a given fishing pole 105 as “faster” or “slower” than a different fishing pole 105.

A fishing pole's 105 action and power may change when line weight is greater or lesser than the fishing pole's 105 specified range. When the line weight used greatly exceeds a fishing pole's 105 specifications a fishing pole 105 may break before the line parts. When the line weight is significantly less than the fishing pole's 105 recommended range the line may part prematurely, as the fishing pole 105 cannot fully flex to accommodate the pull of a given weight fish. In fly rods, exceeding weight ratings may warp the blank or have casting difficulties when fishing poles 105 are improperly loaded.

The action refers to how much a fishing pole 105 bends when a fisherman is casting or have a fish at the end of the line. An extra fast action fishing pole 105 bends just at the tip. A fast action bends in the last quarter of the fishing pole 105. A moderate-fast action fishing pole 105 bends over the last third. A moderate action fishing pole 105 bends over the last half. A slow action fishing pole 105 bends all the way into the handle. Fast action fishing poles 105 put more force into the throw and give the fisherman longer casts. Softer action fishing poles 105 are more forgiving and have less tendency to throw live bait from the hook

Fishing line weight is described in pounds of tensile force before the line parts. A fishing pole 105 is usually also classified by the optimal weight of fishing line or in the case of fly rods, fly line the fishing pole 105 should handle. Line weight for a fishing pole 105 is expressed as a range that the fishing pole 105 is designed to support. Fly rod weights are typically expressed as a number from 1 to 12, written as “N”wt (e.g. 6 wt) and each weight represents a standard weight in grains for the first 30 feet of the fly line established by the American Fishing Tackle Manufacturing Association. For example, the first 30′ of a 6 wt fly line should weigh between 152-168 grains, with the optimal weight being 160 grains. In casting and spinning fishing poles 105, designations such as “8-15 lb. line” are typical. A fishing pole 105 may also be described by the weight of lure or hook that the fishing pole 105 is designed to support. Lure weight is usually expressed in ounces or grams.

Fishing poles 105 that are one piece from butt to tip are considered to have the most natural “feel”, and are preferred by many, though the difficulty in transporting them safely becomes an increasing problem with increasing fishing pole 105 length. Two-piece fishing poles 105, joined by a ferrule, are very common, and if well engineered (especially with tubular glass or carbon fiber fishing poles 105), sacrifice very little in the way of natural feel. Some fishermen do feel a difference in sensitivity with two-piece fishing poles 105, but most do not.

FIG. 1 also shows that the system 100 can include fishing line 110. In at least one implementation, fishing line 110 is a cord used or made for angling. Important parameters of a fishing line 110 can include its length, material, and weight (thicker fishing line 110 can be more visible to fish). Factors that may determine what fishing line 110 an angler chooses for a given fishing environment include breaking strength, knot strength, UV resistance, castability, limpness, stretch, abrasion resistance, and visibility.

In at least one implementation, fishing line 110 can include any material suitable for catching fish. For example, fishing line 110 can include nylon, polyvinylidene fluoride (PVDF, and called fluorocarbon), polyethylene, Dacron and Dyneema (UHMWPE). Fishing line 110 can include monofilament or line made of a single strand. There are also braided fishing lines 110, cofilament and thermally fused lines 110, also known as ‘superlines’ for their small diameter, lack of stretch, and great strength relative to standard nylon monofilament lines.

FIG. 1 shows that the fishing pole 105 can include one or more guides 115. In at least one implementation, the guides 115 can be used to keep the fishing line 110 in line with the fishing pole 105. That is, the guides 115 can be used to ensure that the fishing line 110 goes the length of the fishing pole 105. In particular, the guides 115 can allow the movement of the tip of the fishing pole 105 to control the movement and direction of the fishing line and any attached lures.

FIG. 1 further shows that the system 100 can also include a fishing reel 120. In at least one implementation, the fishing reel 120 includes a device used for the deployment and retrieval of a fishing line using a spool mounted on an axle. In particular, a the fishing reel 120 can include a spool around which the fishing line 110 is wound. A handle 125 allows a user to rotate the spool, winding or unwinding the fishing line 110 as desired. The fishing reel 120 can include a centrepin reel, a bait casting reel, a spinning (fixed spool) reel, a spin cast reel, an underspin reel or any other type of reel.

In at least one implementation, the fishing reel 120 can include a drag mechanism. Drag is a mechanical means of applying variable pressure to the turning spool in order to act as a friction brake against it. It can include a flat spring pressing against the edge of the spool, or a complicated arrangement of leather and Teflon discs. Properly set drag allows larger and more powerful fish to be safely brought to boat and landed, as the drag will “slip” below the breaking point of the fishing line 110, but in combination with the angle of the fishing pole 105, it puts relentless pressure on the fish, quickly tiring it. As a rough general rule, drag is nominally set at about one-half of the line's breaking strength. It can be adjusted up or down as needed by the fisherman while playing a fish, though it takes practice to do this without adding too much drag which frequently results in a broken fishing line 110 and a lost fish. With skillful use of the fishing pole 105 and drag mechanism, fish of greater weight than the fishing line's 110 breaking strength can be successfully played and landed.

FIG. 1 also shows that the system 100 can include a motor 130. In at least one implementation, the motor 130 can be used to convert input energy into mechanical energy. For example, the motor 130 can convert electrical energy into mechanical energy, moving some portion of the motor. Additionally or alternatively, the motor 130 can covert input mechanical energy into mechanical energy that produces a force in a different direction or that magnifies or reduces the forces applied.

In at least one implementation, the motor 130 can include a solenoid. Solenoids consist of an electromagnetically inductive coil, wound around a movable steel or iron slug (termed the armature). The coil is shaped such that the armature can be moved in and out of the center, altering the coil's inductance and thereby becoming an electromagnet. Although typically weak over anything but very short distances, solenoids may be controlled directly by a controller circuit, and thus have very low reaction times. The solenoid can include a spring which returns the solenoid to its original position when power is removed.

In at least one implementation, the motor 130 can be attached to the fishing pole 105. The motor can be attached using any mechanism which ensures that movement of the motor 130 is transferred in whole or in part to the fishing pole 105. For example, the motor 130 can be attached to the fishing pole 105 using a hook and loop fastener, tape, string, a strap, a bolt, a clasp, a latch or through any other mechanism.

In at least one implementation, the motor 130 can be used to automatically jig a fishing lure attached to the fishing line 110. In particular, the motor 130 can move the fishing pole 105 which is transmitted through the fishing line 110 to an attached lure. For example, the motor 130 can be configured to move the tip of the fishing pole 105 between ⅛ inch and ⅜ inches. In particular, the motor 130 can be configured to move the tip of the fishing pole approximately ¼ inch. As used in the specification and the claims, the term approximately shall mean that the value is within 10% of the stated value, unless otherwise specified.

In at least one implementation, the motor 130 can move the fishing pole 105 within a housing, as discussed below. Additionally or alternatively, the motor 130 can be mounted on a boat, on a railing, such as on a pier, on an ice sheet, e.g., on the frozen surface of a lake for ice fishing or in any other location where the motor 130 can move the fishing pole 105.

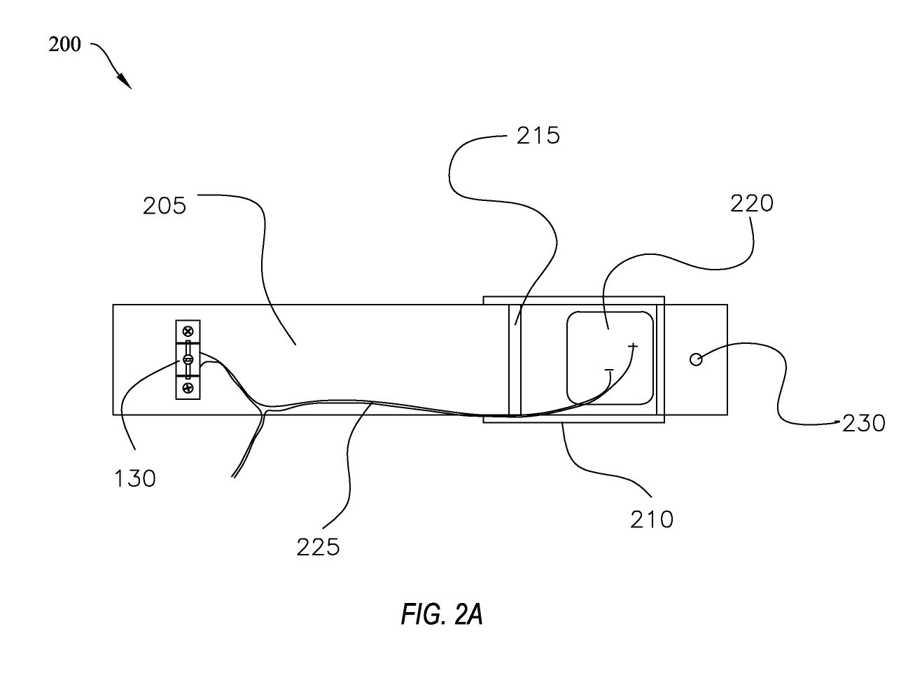

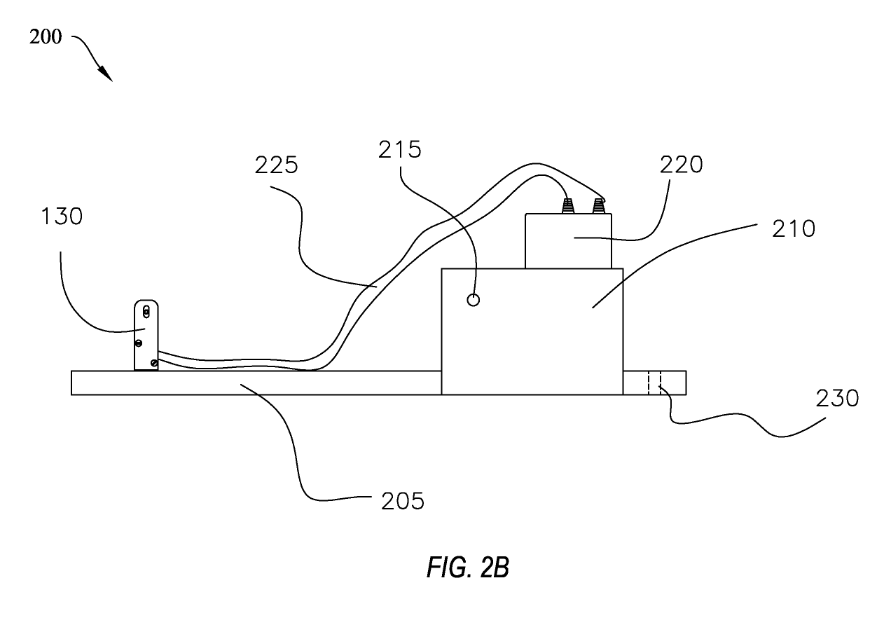

FIGS. 2A and 2B illustrate an example of a housing 200. FIG. 2A illustrates a top view of the housing 200; and FIG. 2B illustrates a side view of the housing 200. One of skill in the art will appreciate that the housing 200 can be used with the system 100 of FIG. 1; however, the housing 200 can be used with a system other than the system 100 of FIG. 1.

FIGS. 2A and 2B show that the housing 200 can include a bottom surface 205. In at least one implementation, the bottom surface 205 can be used for mounting the motor 130. The bottom surface can include any material sufficiently strong to resist the forces involved in the operation of the motor. For example, bottom surface 205 can include wood, metal, plastic or any other suitable material.

FIGS. 2A and 2B also show that the housing 200 can include a restraint 210. In at least one implementation, the restraint 210 can be used to hold a fishing pole. In particular, the restraint 210 can be used to prevent lateral movement of the fishing pole. For example, the restraint 210 can be used to hold the handle of the fishing pole.

FIGS. 2A and 2B further show that the housing 200 can include a dowel 215. In at least one implementation, the dowel 215 can prevent vertical movement of the fishing pole. That is, the restraint 210 and the dowel 215 can prevent both lateral and vertical movement of the fishing pole relative to the housing 200 once the fishing pole has been inserted into the housing 200.

FIGS. 2A and 2B also show that the housing 200 can include a power source 220. In at least one implementation, the power source 220 can provide power to the motor 130. For example, if the motor 130 is electrically driven, the power source 220 can provide the necessary electrical power for the motor 130. Additionally or alternatively, if the motor 130 is pneumatic, the power source 220 can include pressurized gas or fluid.

In at least one implementation, the power source 220 can match the needs of the motor 130. For example, if the motor 130 is a six volt solenoid (i.e., a solenoid that requires six volts for operation), the power source 220 can include a six volt battery or a transformer that produces six volts of electric power. Additionally or alternatively, if the motor 130 requires a certain pressure of gas to operate, the power source 220 can include gas compressed to at or above the necessary pressure.

FIGS. 2A and 2B further show that the housing 200 can include a connector 225. In at least one implementation, the connector 225 can connect the power source 220 to the motor 130. For example, if the power source 220 is an electric power source, the connector 225 can include a wire. Additionally or alternatively, the connector 225 can include a pipe or tube that is configured to transport compressed air or fluid from the power source 220 to the motor 130.

In at least one implementation, the connector 225 can also connect to a switch. The switch can allow a user to operate the motor 130 as desired. In particular, the switch can allow a user to operate the motor 130, which will jig a fishing lure attached to the fishing pole. Additionally or alternatively, the switch can include a timer. The timer can allow the user to set the motor 130 to automatically jig the lure on a regular interval.

FIGS. 2A and 2B show that the housing 200 can also include a hole 230. In at least one implementation, the hole 230 can be used to attach the housing 200 to an external structure. For example, the hole 230 can be used to attach the housing 200 to a boat, an ice surface, a railing, a dock, a pier or any other structure.

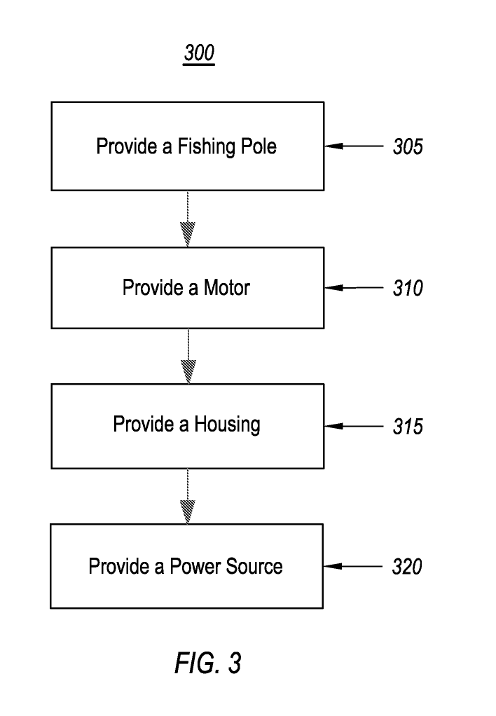

FIG. 3 is a flow chart illustrating a method 300 for manufacturing a system for automatically jigging a lure. One of skill in the art will appreciate that the method 300 can be used to produce the system 100 of FIG. 1; however, the method 300 can be used to produce a system other than the system 100 of FIG. 1.

FIG. 3 shows that the method 300 includes providing a fishing pole 305. In at least one implementation, the fishing pole, is a tool used to catch fish. The fishing pole can include a simple pole or stick. The fishing pole can be made of fiberglass, carbon fiber, graphite, bamboo or any other suitable material. The fishing pole can vary in action as well as length, and can be found in sizes between 24 inches and 20 feet. The longer the fishing pole, the greater the mechanical advantage in casting.

Providing a fishing pole 305 can include providing any type of fishing pole. For example, the fishing pole can include carbon fiber rods, fly rods, spin and bait casting rods, spinning rods, ultra-light rods, ice rods, sea rods, surf rods, trolling rods, telescopic rods or tenkara rods. One of skill in the art will appreciate that the method 300 can be used with any type of fishing pole as described below. There are several specifications manufacturers use to delineate fishing pole uses including power, action, line weight, lure weight, and number of pieces.

Power is often an indicator of what types of fishing, species of fish, or size of fish a particular fishing pole may be best used for. Also known as “power value” or “rod weight.” Fishing poles may be classified as ultra-light, light, medium-light, medium, medium-heavy, heavy, ultra-heavy, or other similar combinations. Ultra-light fishing poles can be used for catching small bait fish and also panfish, or situations where fishing pole responsiveness is critical. Ultra-heavy fishing poles are used in deep sea fishing, surf fishing, or for heavy fish by weight. While manufacturers use various designations for a fishing pole's power, there is no fixed standard, hence application of a particular power tag by a manufacturer is somewhat subjective. Any fish can theoretically be caught with any fishing pole, but catching panfish on a heavy fishing pole offers no sport whatsoever, and successfully landing a large fish on an ultra-light fishing pole requires supreme fishing pole handling skills at best, and more frequently ends in broken tackle and a lost fish. Fishing poles are best suited to the type of fishing they are intended for.

“Action” refers to the responsiveness of the fishing pole to bending force (bending curve), and the speed with which the fishing pole returns to its neutral position. An action may be slow, medium, fast, or a combination (e.g. medium-fast). Fast action fishing poles flex most in the tip section. Slow fishing poles flex more towards the butt of the fishing pole. The construction material and construction method of a fishing pole can affect its action. Action, however, is also often a subjective description of a manufacturer; some manufacturers list the power value of the fishing pole as its action. A “medium” action bamboo fishing pole may have a faster action than a “fast” fiberglass fishing pole. Action is also subjectively used by anglers, as an angler might compare a given fishing pole as “faster” or “slower” than a different fishing pole.

A fishing pole's action and power may change when line weight is greater or lesser than the fishing pole's specified range. When the line weight used greatly exceeds a fishing pole's specifications a fishing pole may break before the line parts. When the line weight is significantly less than the fishing pole's recommended range the line may part prematurely, as the fishing pole cannot fully flex to accommodate the pull of a given weight fish. In fly rods, exceeding weight ratings may warp the blank or have casting difficulties when fishing poles are improperly loaded.

The action refers to how much a fishing pole bends when a fisherman is casting or have a fish at the end of the line. An extra fast action fishing pole bends just at the tip. A fast action bends in the last quarter of the fishing pole. A moderate-fast action fishing pole bends over the last third. A moderate action fishing pole bends over the last half. A slow action fishing pole bends all the way into the handle. Fast action fishing poles put more force into the throw and give the fisherman longer casts. Softer action fishing poles are more forgiving and have less tendency to throw live bait from the hook.

Fishing line weight is described in pounds of tensile force before the line parts. A fishing pole is usually also classified by the optimal weight of fishing line or in the case of fly rods, fly line the fishing pole should handle. Line weight for a fishing pole is expressed as a range that the fishing pole is designed to support. Fly rod weights are typically expressed as a number from 1 to 12, written as “N”wt (e.g. 6 wt) and each weight represents a standard weight in grains for the first 30 feet of the fly line established by the American Fishing Tackle Manufacturing Association. For example, the first 30′ of a 6wt fly line should weigh between 152-168 grains, with the optimal weight being 160 grains. In casting and spinning fishing poles, designations such as “8-15 lb. line” are typical. A fishing pole may also be described by the weight of lure or hook that the fishing pole is designed to support. Lure weight is usually expressed in ounces or grams.

Fishing poles that are one piece from butt to tip are considered to have the most natural “feel”, and are preferred by many, though the difficulty in transporting them safely becomes an increasing problem with increasing fishing pole length. Two-piece fishing poles, joined by a ferrule, are very common, and if well engineered (especially with tubular glass or carbon fiber fishing poles), sacrifice very little in the way of natural feel. Some fishermen do feel a difference in sensitivity with two-piece fishing poles, but most do not.

In at least one implementation, the fishing pole can include fishing line. In at least one implementation, fishing line is a cord used or made for angling. Important parameters of a fishing line can include its length, material, and weight (thicker fishing line can be more visible to fish). Factors that may determine what fishing line an angler chooses for a given fishing environment include breaking strength, knot strength, UV resistance, castability, limpness, stretch, abrasion resistance, and visibility.

In at least one implementation, fishing line can include any material suitable for catching fish. For example, fishing line can include nylon, polyvinylidene fluoride (PVDF, and called fluorocarbon), polyethylene, Dacron and Dyneema (UHMWPE). Fishing line can include monofilament or line made of a single strand. There are also braided fishing lines, cofilament and thermally fused lines, also known as ‘superlines’ for their small diameter, lack of stretch, and great strength relative to standard nylon monofilament lines.

In at least one implementation, the fishing pole can include one or more guides. In at least one implementation, the guides can be used to keep the fishing line in line with the fishing pole. That is, the guides can be used to ensure that the fishing line goes the length of the fishing pole. In particular, the guides can allow the movement of the tip of the fishing pole to control the movement and direction of the fishing line and any attached lures.

In at least one implementation, the fishing pole can also include a fishing reel. In at least one implementation, the fishing reel includes a device used for the deployment and retrieval of a fishing line using a spool mounted on an axle. In particular, the fishing reel can include a spool around which the fishing line is wound. A handle allows a user to rotate the spool, winding or unwinding the fishing line as desired. The fishing reel can include a centrepin reel, a bait casting reel, a spinning (fixed spool) reel, a spin cast reel, an underspin reel or any other type of reel.

In at least one implementation, the fishing reel can include a drag mechanism. Drag is a mechanical means of applying variable pressure to the turning spool in order to act as a friction brake against it. It can include a flat spring pressing against the edge of the spool, or a complicated arrangement of leather and Teflon discs. Properly set drag allows larger and more powerful fish to be safely brought to boat and landed, as the drag will “slip” below the breaking point of the fishing line, but in combination with the angle of the fishing pole, it puts relentless pressure on the fish, quickly tiring it. As a rough general rule, drag is nominally set at about one-half of the line's breaking strength. It can be adjusted up or down as needed by the fisherman while playing a fish, though it takes practice to do this without adding too much drag which frequently results in a broken fishing line and a lost fish. With skillful use of the fishing pole and drag mechanism, fish of greater weight than the line's breaking strength can be successfully played and landed.

FIG. 3 also shows that the method 300 can include providing a motor 310. In at least one implementation, the motor can be used to convert input energy into mechanical energy. For example, the motor can convert electrical energy into mechanical energy, moving some portion of the motor. Additionally or alternatively, the motor can covert input mechanical energy into mechanical energy that produces a force in a different direction or that magnifies or reduces the forces applied.

In at least one implementation, the motor can include a solenoid. Solenoids consist of an electromagnetically inductive coil, wound around a movable steel or iron slug (termed the armature). The coil is shaped such that the armature can be moved in and out of the center, altering the coil's inductance and thereby becoming an electromagnet. Although typically weak over anything but very short distances, solenoids may be controlled directly by a controller circuit, and thus have very low reaction times. The solenoid can include a spring which returns the solenoid to its original position when power is removed.

In at least one implementation, the motor can be attached to the fishing pole. The motor can be attached using any mechanism which ensures that movement of the motor is transferred in whole or in part to the fishing pole. For example, the motor can be attached to the fishing pole using a hook and loop fastener, tape, string, a strap, a bolt, a clasp, a latch or through any other mechanism.

In at least one implementation, the motor can be used to automatically jig a fishing lure attached to the fishing line. In particular, the motor can move the fishing pole which is transmitted through the fishing line to an attached lure. For example, the motor can be configured to move the tip of the fishing pole between ⅛ inch and ⅜ inches. In particular, the motor can be configured to move the tip of the fishing pole approximately ¼ inch.

In at least one implementation, the motor can move the fishing pole within a housing, as discussed below. Additionally or alternatively, the motor can be mounted on a boat, on a railing, such as on a pier, on an ice sheet, e.g., on the frozen surface of a lake for ice fishing or in any other location where the motor can move the fishing pole.

FIG. 3 further shows that the method 300 can include providing a housing 315. The housing can include a bottom surface. In at least one implementation, the bottom surface can be used for mounting the motor. The bottom surface can include any material sufficiently strong to resist the forces involved in the operation of the motor. For example, bottom surface can include wood, metal, plastic or any other suitable material.

In at least one implementation, the housing can include a restraint. The restraint can be used to hold a fishing pole. In particular, the restraint can be used to prevent lateral movement of the fishing pole. For example, the restraint can be used to hold the handle of the fishing pole.

In at least one implementation, the housing can include a dowel. The dowel can prevent vertical movement of the fishing pole. That is, the restraint and the dowel can prevent both lateral and vertical movement of the fishing pole relative to the housing once the fishing pole has been inserted into the housing.

FIG. 3 also shows that the method 300 can include providing a power source 320. The power source can provide power to the motor. For example, if the motor is electrically driven, the power source can provide the necessary electrical power for the motor. Additionally or alternatively, if the motor is pneumatic, the power source can include pressurized gas or fluid.

In at least one implementation, the power source can match the needs of the motor. For example, if the motor is a six volt solenoid (i.e., a solenoid that requires six volts for operation), the power source can include a six volt battery or a transformer that produces six volts of electric power. Additionally or alternatively, if the motor requires a certain pressure of gas to operate, the power source can include gas compressed to at or above the necessary pressure.

In at least one implementation, the method 300 can also include providing a connector. The connector can connect the power source to the motor. For example, if the power source is an electric power source, the connector can include a wire. Additionally or alternatively, the connector can include a pipe or tube that is configured to transport compressed air or fluid from the power source to the motor.

In at least one implementation, the connector can also connect to a switch. The switch can allow a user to operate the motor as desired. In particular, the switch can allow a user to operate the motor, which will jig a fishing lure attached to the fishing pole or attached to fishing line attached to the fishing pole. Additionally or alternatively, the switch can include a timer. The timer can allow the user to set the motor to automatically jig the lure on a regular interval.

In at least one implementation, the method 300 can also include providing a hole. The hole can be used to attach the housing to an external structure. For example, the hole can be used to attach the housing to a boat, an ice surface, a railing, a dock, a pier or any other structure.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A system for automatically jigging a lure, the system comprising:
a fishing pole, wherein the fishing pole includes:
a tip; and
fishing line, wherein the fishing line passes through the tip; and
a motor, wherein the motor is configured to move the tip of the fishing pole.

2. The system of claim 1, wherein the housing includes one of:
wood;
plastic; or
metal.

3. The system of claim 1 further comprising a surface, wherein the motor is attached to the surface.

4. The system of claim 3, wherein the surface includes a sheet of ice.

5. The system of claim 1, wherein the fishing pole includes graphite.

6. The system of claim 1, wherein the fishing pole includes:
fishing line; and
a fishing lure attached to the fishing line.

7. The system of claim 1, wherein the motor includes a solenoid.

8. The system of claim 7, wherein the solenoid includes a spring, wherein the spring is configured to return the solenoid to its original position.

9. A system for automatically jigging a lure, the system comprising:
a housing, wherein the housing is configured to enclose at least a portion of the system;
a fishing pole, wherein the fishing pole includes:
a reel;
a tip;
fishing line, wherein the fishing line is wound around the reel and passes through the tip; and
a lure, wherein the lure:
is attached to the fishing line;
includes a hook; and
is configured to attract and catch fish;
a solenoid, wherein the solenoid is configured to move the fishing pole from a first position relative to the housing to a second position relative to the housing;
a power source, wherein the power source is configured to provide power to the solenoid;
a switch, wherein the switch is configured to activate the solenoid;
a spring, wherein the spring is configured to return the fishing pole from the second position to the first position.

10. The system of claim 9, wherein the location of the tip of the fishing pole in first position is between ⅛ inch and ⅜ inches above the location of the tip of the fishing pole in the second position.

11. The system of claim 10, wherein the location of the tip of the fishing pole in first position is approximately ¼ inch above the location of the tip of the fishing pole in the second position.

12. The system of claim 9, wherein the power source includes a battery.

13. The system of claim 12, wherein the battery includes a six volt battery.

14. The system of claim 12, wherein the battery is configured to match the voltage required by the solenoid.

15. The system of claim 9, wherein the switch is configured to be activated by a user.

16. The system of claim 9, wherein the fishing pole is connected to the solenoid.

17. The system of claim 16, wherein a hook and loop fastener connects the fishing pole to the solenoid.

18. A method of manufacturing system for, the method comprising:
providing a fishing pole, wherein the fishing pole includes:
a tip; and
fishing line, wherein the fishing line passes through the tip; and
providing a motor, wherein the motor is configured to move the tip of the fishing pole.

19. The method of claim 18 further comprising:
providing a timer, wherein the timer is configured to activate the motor at regular intervals.

20. The method of claim 18 wherein the housing is configured to receive an ice stake, wherein the ice stake is configured to attach the housing to ice for ice fishing.
